(19) United States
(12) Patent Application Publication
(10) Pub. No.: US 2024/0305061 A1
(43) Pub. Date: Sep. 12, 2024

(54) DEVICE AND METHOD FOR CONTROLLING A LIGHT SOURCE IN A MICROSCOPE

(71) Applicant: Carl Zeiss Microscopy GmbH, Jena (DE)

(72) Inventors: Stefan WILHELM, Jena (DE); Burkhard ROSCHER, Jena (DE); Tiemo ANHUT, Jena (DE)

(73) Assignee: Carl Zeiss Microscopy GmbH, Jena (DE)

(21) Appl. No.: 18/598,024

(22) Filed: Mar. 7, 2024

(30) Foreign Application Priority Data
Mar. 7, 2023 (DE) 102023105639.5
Apr. 17, 2023 (DE) 102023109613.3

(51) Int. Cl. H01S 5/0683; G02B 21/06

(52) U.S. Cl. CPC H01S 5/0683; G02B 21/06

(57) ABSTRACT

The present invention relates to a device for driving a light source for a microscope, the device comprising: a current source, for supplying the light source with a coarse driving current, a small signal generator, for supplying the light source with a fine driving current. The sum of the coarse driving current and of the fine driving current results in a driving current for the light source, wherein the fine driving current has a magnitude smaller than the coarse driving current. The invention further relates to a method for controlling said device.

### FIELD OF THE INVENTION

The present invention generally relates to the field of microscopy. In particular, it relates to devices for irradiating a sample being imaged by a microscope and for driving a light source used for such irradiation, as well as to the microscope itself. Embodiments of the invention also relate to methods for operating such devices.

### BACKGROUND OF THE INVENTION

Scanning microscopy generally involves irradiating a light source, such as a laser beam, onto a sample and scanning the resulting image. In some cases, the sample is only illuminated by the light. In some other cases, the sample itself can emit light when excited by the light source, and the scanned image can comprise the emitted fluorescent light. The scanned image generally comprises a plurality of lines, and/or rows, each comprising a plurality of pixels, in a known manner.

For imaging procedures in microscopy, it is often necessary to optimise the switch-on behaviour of a light source via pre-compensation, in order to compensate for effects on the intensity curve from the rapid change of the thermal load. This pre-compensation can be implemented by an analog regulator, which can be implemented as an RC-circuit. The analog regulator can be tuned for the type of light source LS used, or even for the specific light source LS mounted on a given PCB.

This implementation enables precise control of the current I_{L} and thus the realisation of very short and precise rise times for the light source, in the order of 20 ns, or even less. This, in turn, requires that the elements of the RC-circuit implementing the analog regulator are selected for the given light source LS and then manually soldered, with an impact on production time and costs.

From a production perspective, it is therefore preferable to implement a digital controller, since the digital controller can be identical for all PCBs and then adapted, if needed, to the characteristic of the specific single light source LS mounted on a given PCB. This can be implemented as schematically illustrated in FIG. 1.

In particular, the device 100 for irradiating a sample of FIG. 1 comprises a digital controller 140. The digital controller 140 can be implemented by a circuit comprising at least a resistance and a capacitance, whose value can be digitally varied based on a control signal, not illustrated, inputted to the digital controller. Thanks to this change, the RC characteristic of the digital controller can be changed digitally, so that it can be adapted to the specific characteristics of the load. This is particularly advantageous in comparison with the analog regulator, where instead the RC characteristic is fixed by the use of a specific resistance and capacitance, which are chosen based on the specific characteristics of the load that the analog regulator is connected to.

This, in turn, can require the analog signal V_{TARG} to be converted back to a digital one, by means of the A/D converter, not illustrated. Alternatively, a digital value can be used for V_{TARG}, as illustrated. In some embodiments, the signal V_{TARG} can also be processed by a further digital controller 170. The controller 170 can be implemented by various devices including, for instance, an FPGA.

One disadvantage of this approach is that the digital controller 140 introduces a significant delay in the propagation time of the signal V_{TARG} to the light source LS.

In particular, propagation time T₁ can be significantly slow for some applications. The digital controller 140 alone can introduce a latency on propagation time T₁ of approximately 250 ns.

This increase in latency drastically reduces the capabilities of the microscope to operate on a pixel by pixel basis.

In particular, in order to operate a microscope, a specific timing correlation is needed between the irradiation with the light source and the scanning of the sample. This is even more so in case of fluorescence microscopy, since the sample will only emit fluorescent light when irradiated, or for a limited amount of time thereafter. It is further difficult to know, a priori, what configuration of the light source provides the best result in the sample. That is, different values of frequency and/or intensity of the light source can result in better or worse imaging and/or fluorescence in the sample. This might further change for different sections of the sample, as they might have different characteristics.

It is thus generally preferable to be able to control configuration of the light source based on the feedback provided by the scanned image. It is thus advantageous to be able to quickly react to a feedback from the scanned pixels and use this information to control the configuration of the light source. By doing so, the configuration of the light source can be adapted, and the sample is progressively irradiated and scanned. Preferably such control of the light source configuration should be performed on a section of the sample as small as possible, as this improves the scanned image. Even more preferably, the control should be possible on a pixel by pixel basis.

With the configuration of FIG. 1, such operation is not possible due to the high latency time of the driving path of the light source, particularly due to the high latency T₁.

### SUMMARY OF THE INVENTION

There is therefore a need to overcome one or more of the disadvantages indicated above.

In particular, aspects of the invention provide a device for irradiating a sample which simplifies manufacturing, and avoids the disadvantages associated with the high latency time of the digital controller, by bypassing this component to access the light source directly with a control signal. This, in turns, makes it possible to use the digital controller, which eliminates the need to use components measured and assembled for a specific light source, as done in the analog regulator.

Thanks to this configuration, the digital controller allows its RC characteristics to be controlled digitally, thus enabling a simpler manufacturing, while bypassing of the digital controller with the control signal enables a fast control of the light source. In some embodiments, the device can thus allow change of the characteristics of the light source on a pixel by pixel basis.

An embodiment of the invention can relate to a device for driving a light source for a microscope. The device can comprise a current source for supplying the light source with a coarse driving current, and a small signal generator, for supplying the light source with a fine driving current. The sum of the coarse driving current and of the fine driving current can in particular result in a driving current for the light source. The coarse driving current can have a magnitude larger than the fine driving current.

Thanks to this implementation, it is advantageously possible to control a part of the driving current through the small signal generator, which can be configured to have a smaller latency than the current source supplying the coarse driving current. This enables the device to operate with a smaller latency, within the range of capability of the small signal generator.

In some embodiments, the coarse driving current can have a magnitude at least 5 times, preferably at least 10 times, even more preferably at least 20 times, larger than the fine driving current.

Thanks to this implementation, it is advantageously possible to have a majority of the driving current provided through the current source, while leaving the small signal generator with the task of providing only a minority of the driving current.

In some embodiments, the device can further comprise a controller configured to control operation of the small signal generator. In particular, the controller can be configured to output a digital signal for controlling an intensity of the driving current, the digital signal comprising one or more most significant bits and one or more least significant bits. More specifically, the controller can be configured to output the one or more least significant bits to the small signal generator.

Thanks to this implementation, it is advantageously possible to control the small signal generator by using a part of the digital signal for controlling the intensity of the driving current. Advantageously, this leaves the remaining part of the digital signal available for controlling the current source, which provides the coarse driving current.

In some embodiments, the device can further comprise a digital controller, for controlling a value of the coarse driving current. It is preferred that the small signal generator has a latency at least ten times lower than the digital controller.

Thanks to this implementation, it is advantageously possible to control the part of the driving current provided by the small signal generator with a low latency.

In some embodiments, the microscope can comprise a sensor for sensing light from a sample irradiated by the light source. The device for driving the light source can be configured to receive a feedback signal from the sensor, indicative of the amount of light measured by the sensor. The device for driving the light source can be configured to control the fine driving current based on the feedback signal.

Thanks to this implementation, it is advantageously possible to control the amount of the fine driving current based on the feedback provided by the sensor. In preferred embodiments, this enables a pixel-by-pixel control of the driving current, through modulation of the fine driving current by the small signal generator.

A further embodiment can relate to a device for irradiating a sample under a microscope. The device for irradiating the sample can comprise a device for driving a light source according to any previous embodiment, and a light source.

In some embodiments, the light source can be a laser diode.

A further embodiment can relate to a microscope, especially a laser scanning microscope, comprising the device for driving the light source according to any previous embodiment, or the device for irradiating a sample according to any previous embodiment.

A further embodiment can relate to a method for controlling a device for driving a light source for a microscope. The method can comprise a step of generating a coarse driving current with a current source, and a step of generating a fine driving current with a small signal. The method can further comprise a step of driving the light source with a driving current resulting from the sum of the coarse driving current and of the fine driving current. In particular, the fine driving current can have a magnitude smaller than the coarse driving current.

In some embodiments, the method can further comprise a step of receiving a feedback signal from a sensor for sensing light from a sample irradiated by the light source, the feedback signal being indicative of the amount of light measured by the sensor. The method can further comprise a step of adjusting the fine driving current based on the feedback signal.

Thanks to this implementation, it is advantageously possible to control the amount of the fine driving current based on the feedback provided by the sensor. In preferred embodiments, this enables a pixel-by-pixel control of the driving current, through modulation of the fine driving current by the small signal generator.

### BRIEF DESCRIPTION OF THE DRAWINGS

FIG. 1 schematically illustrates a device 100 for irradiating a sample;

FIG. 2 schematically illustrates a device 201 for driving a light source LS and a corresponding device 202 for irradiating a sample in a microscope 200;

FIG. 3 schematically illustrates a device 301 for driving a light source LS and a corresponding device 302 for irradiating a sample in a microscope 300;

FIG. 3A schematically illustrates an exemplary operation of a small signal generator;

FIG. 4 schematically illustrates a method 400 for controlling a device for driving a light source for a microscope.

### DETAILED DESCRIPTION OF THE INVENTION

The inventors have generally realized that a digital controller can be implemented in the diving chain of the light source, even if the latency introduced by the regulator is too long, by additionally using a small signal generator in addition to the current source controlled by the digital controller.

In general, this allows the current source controlled by the digital controller to provide a basis, or course, current, while a finer, and faster, control of the driving current can be achieved by means of the small signal generator, which can react faster than the digital controller.

The invention therefore allows a fast adjustment of the driving current around a, slower, coarse value, which enables a pixel-by-pixel control of the driving current and thus of the intensity of the light source.

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired.

It is recognized that any circuit or other electrical device disclosed herein may include any number of microcontrollers, integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the invention will be described in detail with reference to the accompanying drawings. It is to be understood that the following description of embodiments is not to be taken in a limiting sense. The scope of the invention is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

FIG. 2 schematically illustrates a device 201 for driving a light source LS and a corresponding device 202 for irradiating a sample in a microscope 200. The microscope 200 is only very schematically represented by the sensor 290, which picks up the light reflected and/or irradiated by the sample. It will be clear to those skilled in the art that further elements, such as lenses, are generally implemented and have not been illustrated for clarity of illustration.

In particular, device 201 is configured for driving the light source LS, which can be implemented as part of a microscope 200, in particular for illuminating a sample being examined under the microscope 290. More specifically, by illuminating the sample with light emitted by the light source LS, the sample either reflects or irradiates light, for instance due to fluorescence, which is then picked up by the sensor 290, in a manner per se known.

The light source LS can be any of a laser diode, a laser, a diode, or in general any device capable of emitting light. In preferred embodiments, the light source LS has a rise time lower than 200 ns, preferably lower than 100 ns, even more preferably lower than 30 ns. Here by rise time it is intended a time elapsing between a sufficiently high driving signal being supplied to the light source LS and the light source LS emitting light. Rise times in this order of magnitude can be achieved with known light sources and can enable fast modulation of the light emitted by the light source LS.

However, if the latency of the control signal of the light source LS is too high compared to the rise time of the light source LS, then the signal controlling the light source LS becomes too slow for enabling a pixel by pixel adjustment of the light source. Even more specifically, if the latency of the control signal of the light source LS is higher than the duration of illumination of a pixel, which is usually higher than the rise time of the light source LS, then a pixel-by-pixel adjustment has been generally considered not to be possible.

The present invention allows solving this problem by introducing a small signal generator, which allows at least part of the control signal to bypass the digital controller 140, as will be described more in details in the following.

In particular, the device 201 comprises a current source 150 for supplying the light source LS with a coarse driving current I_{COARSE} and a small signal generator 280 for supplying the light source LS with a fine driving current I_{FINE}. As visible in FIG. 2, the sum of the coarse driving current I_{COARSE} and of the fine driving current I_{FINE} results in driving current I_{L}, which is used for driving the light source LS.

In this manner, by changing either of the coarse driving current I_{COARSE} or the fine driving current I_{FINE}, the driving current I_{L} can be changed. Preferably, the coarse driving current I_{COARSE} has a magnitude larger than the fine driving current I_{FINE}.

This is particularly advantageous since the latency of driving a current generator is usually higher, as the current capability of the generator increases. Thus, by providing a smaller current capability at the fine driving current I_{FINE} compared to the coarse driving current I_{COARSE}, it is possible to obtain a lower latency in the driving of the fine driving current I_{FINE} compared to the coarse driving current I_{COARSE}.

In particular, in preferred embodiments, the coarse driving current I_{COARSE} can have a magnitude at least 5 times, preferably at least 10 times, even more preferably at least 20 times, larger than the fine driving current I_{FINE}. Here the magnitude can be understood to be the respective absolute maximum magnitude, or a RMS measurement of the respective current, or other known manners of quantifying a magnitude of a variable signal.

Moreover, the configuration of device 201 is advantageous since it allows the regulation of the coarse current I_{COARSE} to be controlled by the signal going through the digital controller 140, which can be configured on the basis of the physical characteristics of the light source LS, as previously described, while nevertheless allowing a fast modulation of the driving current I_{L}, through the small signal generator 280, which does not suffer from the latency introduced by the digital controller 140.

That is, the device 201 can comprise a digital controller 140, for controlling a value of the coarse driving current I_{COARSE}. The digital controller 140 can in particular be configured to control the first current source 150 based on an input signal and based on a predetermined configuration which depends on the physical characteristics of the light source LS.

More specifically, the presence of the digital controller 140 in the controlling chain of the coarse current I_{COARSE} allows a pre-compensation of the drive signal received as input, to provide an output which is matched to the current source 150 and/or to the light source LS, or their combination. In particular, the matching is done so as to reduce the transient response time of the light source LS. Alternatively, or in addition, the matching is done so as to increase similarity between the curve of the intensity of the light, outputted by the light source LS, and the curve of the drive signal, inputted to the regulator 140.

It will be clear to those skilled in the art that this can be achieved in several manners through the use of known circuits topologies. In some embodiments, the digital controller 140 can comprise at least a variable resistor R and a variable capacitance C, and the compensation can be achieved by changing the RC characteristics of the digital controller 140. More generally, the digital controller 140 can comprise a plurality of resistors and/or capacitances with variable values, which can be controlled by an external input, so as to configure the digital controller 140 in order to provide a pre-compensation which is fitting the physical characteristics of the current source 150 and/or of the light source LS, or of their combination.

Nevertheless, the presence of the digital controller 140, as previously discussed, introduces a latency on the signal controlling the coarse current I_{COARSE}. That is, the time difference from a variation on the input of the digital controller 140, and a respective variation on its output, can be significant with respect to the time requirements at which the driving current I_{L} needs to be switched. In terms of current technology, the latency introduced by the digital controller 140 can be in the order of μs, which can be too high for a pixel-based control of the intensity of the light emitted by the light source LS. Independently on its value, which is technology dependent, when the latency is larger than the time requirements at which the driving current I_{L} needs to be switched, and in particular when the latency is larger than the rise time of the light source LS, it is not possible to achieve a fast modulation within a single pixel, or from pixel to pixel.

On the other hand, as will be explained more in details below, in some embodiments of the invention, at least part of the control signal of the light source LS can have a latency which is lower than the rise time of the light source LS, preferably at least an order of magnitude lower. This allows using the full bandwidth of the light source LS.

In particular, in the invention, the latency introduced by the digital controller 140 is circumvented by providing a faster path by means of the small signal generator 280.

In particular, in some embodiments of the invention, the digital controller 140 can have a latency higher than the rise time of the light source LS, and/or higher than the time duration of illumination of a pixel. That is, the sample can be illuminated and scanned on a pixel-by-pixel basis, wherein each pixel can be illuminated for a given time duration. The latency can be longer than said time duration. Thus, it follows that it is not possible to modulate the driving current I_{L} during the illumination of a single pixel with a signal going through the digital controller 140, as the latency does not allow a sufficiently fast reaction.

The invention overcomes this problem by providing a faster path for controlling the driving current I_{L} through the small signal generator 280.

In particular, in some embodiments, the small signal generator 280 can have a latency lower than the digital controller 140. Preferably the small signal generator 280 can have a latency lower than the time of illumination of a single pixel. Alternatively, or in addition, the small signal generator 280 can have a latency comparable to, or smaller than, the rise time of the light source LS, preferably at least 2 times smaller, even more preferably at least 10 times smaller. Still alternatively, or in addition, the small signal generator 280 can have a latency comprised between the rise time of the light source LS and the time of illumination of a single pixel. In some embodiments, the small signal generator 280 can have a latency preferably lower than 10 ns, more preferably lower than 5 ns.

This can be advantageously achieved with known circuits, since the small signal generator 280 does not need to implement a regulation specific to the light source, contrary to the digital controller 140. Due to this, the small signal generator 280 can be more simply implemented than the digital controller 140, thus leading to a smaller latency. Moreover, since the small signal generator 280 needs to drive a lower current than the digital controller 140, this can also lead to a lower latency as the electronic elements of the small signal generator 280 can operate at a faster rate due to the lower current needs.

The small signal generator 280 can in particular be implemented with any circuit capable of generating and/or controlling a current. For instance, any of a current generator, a current mirror, a current steering circuit can be used to implement the small signal generator 280.

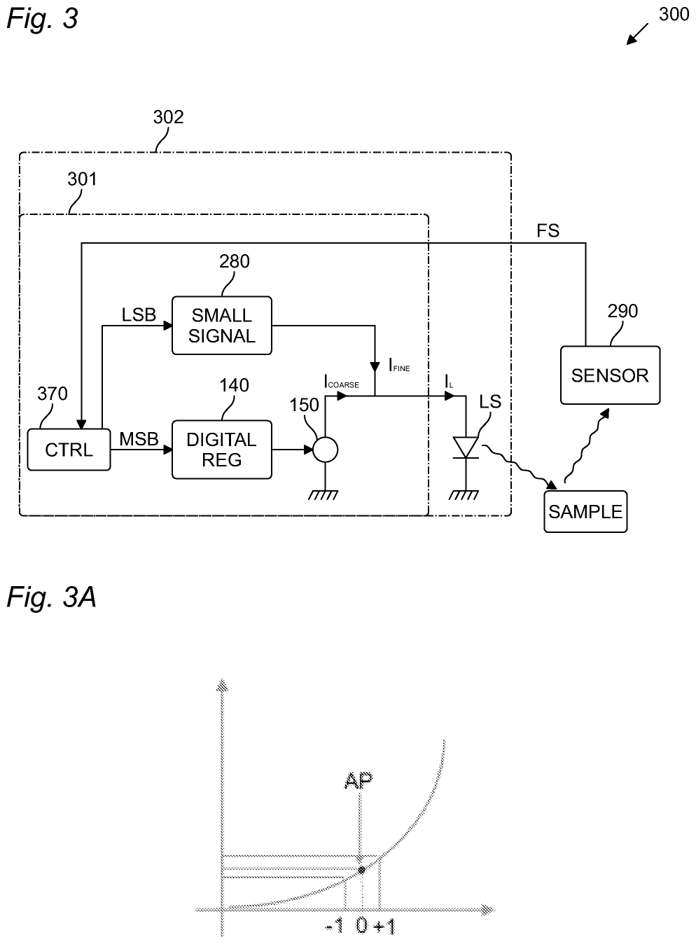

In particular, FIG. 3A schematically illustrates how the operation of a small signal generator 280 can modulate the total driving current provided to the light source LS. More specifically, the vertical axis schematically illustrates the driving current and the horizontal axis schematically illustrated the signal for controlling the driving current. The point AP illustrates a working point, which can for instance correspond to the current I_{COARSE}.

As visible in FIG. 3A, the small signal generator 280 can operate within a smaller range of the controlling signal along the horizontal axis. This smaller range is schematically illustrated as being comprised between −1 and +1, it will however be clear to those skilled in the art that numerical values might differ in practical embodiments, and that the range of −1 to +1 can be understood as being normalized to the operating range of the small signal generator.

As further visible in FIG. 3A, the small signal generator 280 can result in a corresponding small variation of the total driving current along the working point AP. This small variation, which corresponds to the variation introduced by the current I_{FINE} can be positive or negative, depending on the specific implementation and on the requested modulation of I_{COARSE}.

The small signal generator 280 can drive the current I_{FINE} based on various inputs. It will however be clear that, in some potential embodiments, the invention does not always necessarily need a specific input for driving small signal generator 280.

For instance, in some embodiments, the small signal generator 280 can apply a predetermined variation pattern on the current I_{FINE}. In particular, a controller 281 can be configured to control the small signal generator 280 so as to result in the small signal generator 280 to apply the predetermined variation pattern. Preferably, the predetermined variation pattern can be configured to modulate the current I_{FINE} within a predetermined range. Even more preferably, the predetermined variation pattern can be configured to modulate the current I_{FINE} around a working point, which is set the current I_{COARSE}.

For instance, with the current I_{COARSE} set at a given value, the current I_{FINE} can increase the current I_{COARSE} by a predetermined value, preferably at least 1% and/or most 10% of I_{COARSE}. Alternatively, or in addition, the current I_{FINE} can decrease the current I_{COARSE} by a predetermined value, preferably at least 1% and/or most 10% of I_{COARSE}. Also for instance, with the current I_{COARSE} set at a given value, the current I_{FINE} can stepwisely increase the current I_{COARSE} by steps of a predetermined value, each step being preferably at least 1% and/or most 10% of I_{COARSE}. Alternatively, or in addition, the current I_{FINE} can decrease the current I_{COARSE} by steps of a predetermined value, each step being preferably at least 1% and/or most 10% of I_{COARSE}.

If the predetermined values described above are expressed as an amount depending on the value of with the current I_{COARSE}, in some embodiments the controller 281 can receive the value of I_{COARSE}. Alternatively, the predetermined values described above can also be implemented as a value independent of I_{COARSE}.

It will be clear that the examples above are not limiting the invention and that a number of predetermined variation pattern can be implemented. This implementation allows a predetermined type and amount of intensity variations to be implemented by the light source. In particular, variations can be implemented without any feedback from the sample, contrary to, for instance, the embodiments illustrated in FIGS. 2 and 3, thus simplifying the construction of the device.

In preferred embodiments, as visible in FIG. 2 a signal output by the sensor 290 can be used as basis for controlling the value of I_{FINE}. That is, the sensor 290 of the microscope can output a signal indicative of the light being measured on a given pixel of the sample. This signal, which might be a specific signal for the purpose of device 201, or might be the detected signal the microscope uses in order to create a picture of the sample, can be provided as a feedback signal FS to devices 202, and 201.

That is, the microscope 200 can comprise a sensor 290 for sensing light from a sample irradiated by the light source LS, and the device 201 can be configured to receive a feedback signal FS from the sensor 290 indicative of the amount of light measured by the sensor 290. The device 201 can then generally be configured to control the fine driving current I_{FINE} based on the feedback signal FS. While not illustrated, the feedback signal FS can be processed and/or converted before being inputted to the controller 281.

Thanks to the feedback signal FS, the value of the fine current I_{FINE} can therefore be advantageously modulated to take into account the amount of light measured by the sensor 290. In some embodiments, the feedback signal FS can be the only basis for controlling the value of the fine current I_{FINE}, however the invention is not limited thereto and the value of I_{FINE} can be controlled based on a plurality of parameters, one of them being the feedback signal FS.

Generally, if the feedback signal FS indicates an illumination of the sample above a predetermined threshold, the value of I_{FINE} can be controlled so as to lower the driving current I_{L}. Conversely, if the feedback signal FS indicates an illumination of the sample below a predetermined threshold, the value of I_{FINE} can be controlled so as to increase the driving current I_{L}.

Thanks to the use of the feedback signal FS and the fast reaction possible through the small signal generator 280, it is therefore possible to adjust the value of the driving current on a pixel-by-pixel basis, and even on an intra-pixel basis.

As further visible in FIG. 2, the device 201 further comprises a controller 270 for controlling operation of the digital controller 140. The controller 270 can be understood to therefore drive at least a baseline value of the current, namely I_{COARSE}, based on inputs provided to the controller 270, for instance by a CPU and/or by a user. The controller 270 can in particular provide a digital value to the digital controller 140 which indicates a value of the intended illumination and/or of the intended I_{COARSE}. The digital controller 140 can then appropriately convert this value as needed to fit the physical characteristics of the light source LS and/or of the current source 150.

It has thus been described how a component I_{COARSE} of the driving current can be generated in a manner which takes into account the physical characteristics of the light source LS and/or of the current source 150, thus enabling an efficient driving of the light source LS.

Contrary to the prior art, this can be achieved without requiring a complex and expensive analog regulator, as in the prior art, but relying instead on a simpler and more flexible digital controller 140, thus enabling a faster production and easier configuration of the device. In particular, a single type of digital controller 140 can be configured to fit a plurality of characteristics of various light sources LS, by merely configuring the digital controller 140 after installation. Moreover, the flexibility introduced by the digital controller 140 could in principle also allow the configuration of the digital controller 140 to also be changed during the operating lifetime of the device. For instance, the configuration of the digital controller 140 could be used to compensate aging effects on the physical characteristics of the light source LS and/or of the current source 150, which would not be possible with a custom analog regulator.

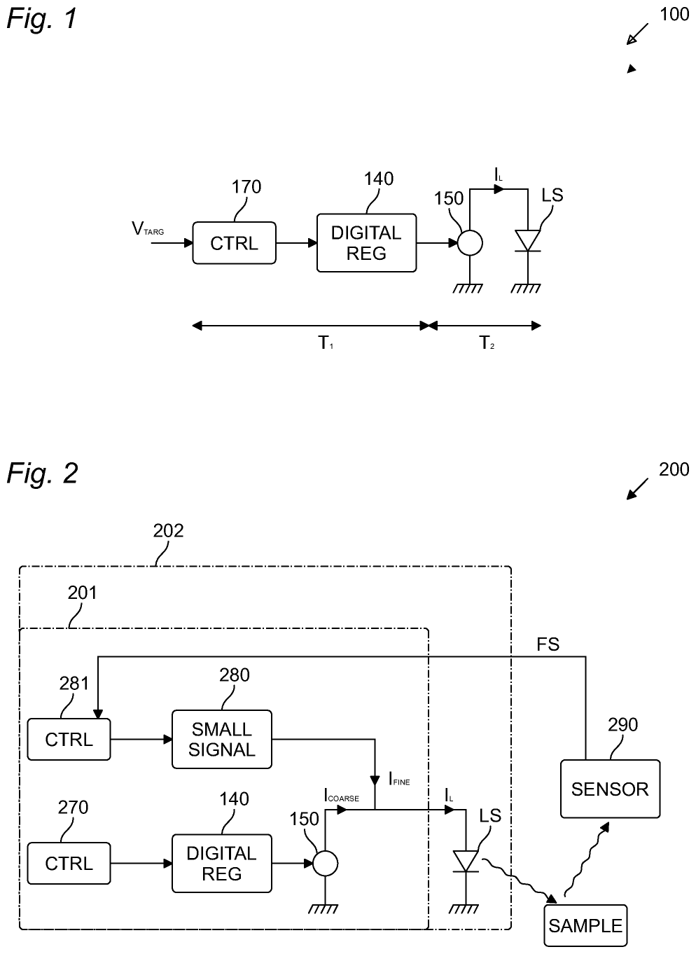

The increased latency introduced by the digital controller 140 would normally prohibit a pixel-by-pixel modulation of the light emitted by the light source LS, as described with reference to FIG. 1. However, in the invention, this problem can be overcome, as the small signal generator 280 has a latency value low enough to enable pixel-by-pixel, or even intra-pixel modulation of the driving current I_{L} by modulating the value of I_{FINE}. That is, the problem associated with the long latency of the digital controller can be overcome by the invention, while still maintaining all the advantages of the digital controller, thanks to the small signal modulation performed through the small signal generator 280.

While the embodiment of FIG. 2 has been described with reference to device 201, namely the device for driving the light source LS, it will be clear that the invention can also be implemented in form of device 202, that is, the device for irradiating sample, comprising device 201 and the light source LS. In some cases, the invention might also be implemented as microscope 200, comprising device 202 and at least the sensor 290 of the microscope.

In particular, for any of the embodiments described as a device for driving a light source LS the invention can also be implemented as a corresponding device for irradiating a sample under a microscope, the device for irradiating the sample comprising the device for driving the light source LS and the light source LS. Similarly, the invention can relate to a microscope comprising the device for driving the light source LS.

FIG. 3 schematically illustrates a device 301 for driving a light source LS and a corresponding device 302 for irradiating a sample in a microscope 300.

The embodiment of FIG. 3 differs from the embodiment of FIG. 2 mainly in that the controller 370 is further configured to control operation of the small signal generator 280. That is, in addition to controlling the value of I_{COARSE} through the digital controller 140, the controller 370 can also control the value of I_{FINE} through the small signal generator 280.

In the specific implementation illustrated in FIG. 3, this can be achieved by the controller 370 being configured to output a digital signal for controlling the level of the driving current I_{L}, the digital signal comprising, or in some embodiments consisting of, one or more most significant bits MSB and one or more least significant bits LSB. Preferably, the number of most significant bits is higher, preferably significantly higher, than the number of least significant bits. Even more preferably, the number of most significant bits is at least twice the number of least significant bits. Even more preferably, the number of most and least significant bits is such that the most significant bits allow controlling of at least 90% of the value of the driving current I_{L} and/or the least significant bits allow controlling of at most 10% of the value of the driving current I_{L}.

The controller 370 can then be configured to output the one or more most significant bits MSB to the digital controller 140 and output the one or more least significant bits LSB to the small signal generator 280. That is, the value of I_{COARSE} can be set by the one or more most significant bits MSB driving the digital controller 140 and thus the current generator 150. Similarly, the value of I_{FINE} can be set by the one or more least significant bits LSB driving the small signal generator 280.

In this manner, a single controller 370 can operate both the slower modulation of the driving current I_{L} through the MSB and the faster, intra-pixel or pixel-by-pixel modulation through the LSB. This is particularly advantageous as it allows a single interface, through the controller 370, to the value of the driving current I_{L}.

In the embodiment of FIG. 2, the feedback signal FS is illustrated as being provided to the controller 281, connected to the small signal generator 280. The invention is however not limited thereto and alternative, or additional, implementations are possible. For instance, as illustrated in FIG. 3, the feedback signal FS can be provided to the controller 370, which can then be configured to use the feedback signal FS as basis for the computation of at least the least significant bits LSB, preferably as basis for the computation of only the least significant bits LSB. The same considerations previously made for the number of least significant bits LSB and most significant bits MSB can also apply to the embodiment of FIG. 3.

Still alternatively, or additionally, device 201 or 301 can further comprise a converter configured to convert the feedback signal FS into a converted feedback signal CFS based on predetermined characteristics. The converter can be implemented, for instance, by a processor or a controller. It will be clear that, in some embodiments, the operation of the converter can be integrated together with the operation of any other controller previously described.

For instance, the converter can be implemented together with the controller 281, here not illustrated, when the converted feedback signal CFS is used to control the small signal generator 280 directly. Alternatively, or in addition, in case the converted feedback signal CFS is used to control the small signal generator 280 through the control of the least significant bits, LSB, the converter can be implemented together with the controller 370. That is, the converter is to be understood as a logical entity and not necessarily as a separate physical entity.

For instance, the converter could comprise a comparator, configured to compare the feedback signal with a predetermined threshold, as previously described. Alternatively, or in addition, the converter could comprise a look-up-table, configured to convert the feedback signal FS based on a predetermined programming of the values of the look-up-table.

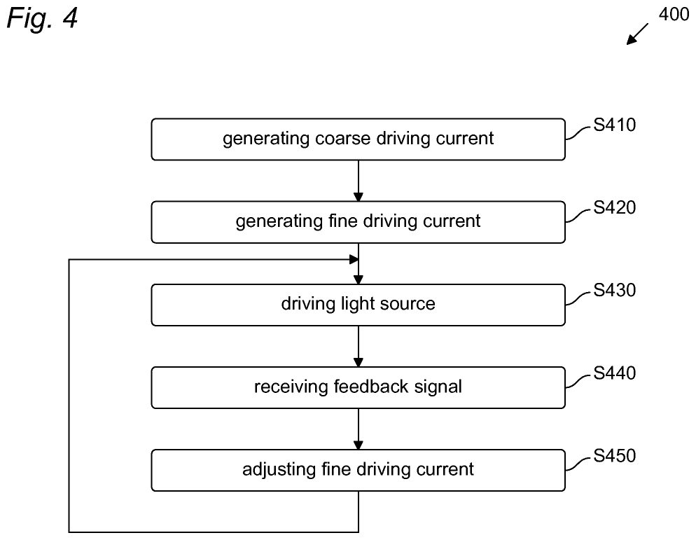

FIG. 4 schematically illustrates a method 400 for controlling a device for driving a light source for a microscope.

In particular, the method 400 can be implemented for controlling any of the previously described devices 201, 301 for driving a light source LS, or any of the corresponding devices 202, 302 for irradiating a sample under a microscope a microscope 200, 300.

The method 400 can comprise a step S410 of generating a coarse driving current I_{COARSE} with a current source 150. The coarse driving current I_{COARSE} can be controlled by a control signal outputted by the digital controller 140 in a manner which depends on the configuration of the current source 150 and will be clear to those skilled in the art.

The method 400 can further comprise a step S420 of generating a fine driving current I_{FINE} with a small signal generator 280, 280. Also in this case, the fine driving current I_{FINE} can be controlled in a manner which depends on the configuration of the small signal generator 280, 280 and how this is controlled, and will be clear to those skilled in the art.

The method 400 can further comprise a step $430 of driving the light source LS with a driving current I_{L} resulting from the sum of the coarse driving current I_{COARSE} and of the fine driving current I_{FINE}, wherein the fine driving current I_{FINE} has a magnitude smaller than the coarse driving current I_{COARSE}, as previously described. In general, the considerations made in the previously described devices apply also to the method 400.

In some embodiments, the method 400 can further comprise a step S440 of receiving a feedback signal FS from a sensor 290 for sensing light from a sample irradiated by the light source LS, the feedback signal FS being indicative of the amount of light measured by the sensor 290, and a step S450 of adjusting the fine driving current I_{FINE} based on the feedback signal FS. As previously described, in some embodiments, the feedback signal FS can be converted into a converted feedback signal CFS, the considerations previously made in this respect also apply to the method 400. The deriving method 400, as well as the previously described devices, therefore enable controlling of the light intensity on a pixel-by-pixel, or possibly even on an intra-pixel basis. This can be used, for instance, to apply a correct amount of light to the subject, by controlling the driving current I_{FINE} as needed. Advantageously, this can be achieved based on a feedback from the sample, schematically illustrated as the feedback signal FS in the figures.

Thanks to this implementation, it is possible to correct the driving light in a fast manner based on the feedback provided by the sample, through the control of I_{FINE}, so as to ensure that the pixels are correctly illuminated.

As previously described, some embodiments of the invention can however be implemented without a feedback. In particular, as described with reference to FIG. 2, the amount of I_{FINE} can be modulated in a predetermined manner by controller 281.

While various embodiments have been illustrated and described, each embodiment comprising one of more features, it will be clear to those skilled in the art that the invention can also be implemented otherwise. In particular, alternative embodiments can be obtained by combining one or more the described features together, preferably within the scope of the claims.

What is claimed is:

1. A device for driving a light source for a microscope, the device comprising:
a current source, for supplying the light source with a coarse driving current,
a first signal generator, for supplying the light source with a fine driving current,
wherein the sum of the coarse driving current and of the fine driving current results in a driving current for the light source,
wherein the coarse driving current has a magnitude larger than the fine driving current.

2. The device according to claim 1 wherein the coarse driving current has a magnitude that is at least one of
at least 5 times larger than the fine driving current,
at least 10 times larger than the fine driving current, or
at least 20 times larger than the fine driving current.

3. The device according to claim 1, further comprising a digital controller, for controlling a value of the coarse driving current while a latency time of the first signal generator is at least ten times smaller than the latency time of the digital controller.

4. The device according to claim 1, further comprising a controller configured to control operation of the first signal generator,
wherein the controller is configured to
output a digital signal for controlling an intensity of the driving current, the digital signal
comprising one or more most significant bits and one or more least significant bits),
output the one or more least significant bits to the first signal generator.

5. The device according to claim 1, further comprising a digital controller, for controlling a value of the coarse driving current, wherein the first signal generator has a latency lower than the digital controller.

6. The device according to claim 1, wherein the microscope comprises a sensor for sensing light from a sample irradiated by the light source, wherein the device is configured to receive a feedback signal from the sensor indicative of the amount of light measured by the sensor, and wherein the device is configured to control the fine driving current based on the feedback signal.

7. A device for irradiating a sample under a microscope, the device comprising:
the device for driving a light source according to claim 1; and
a light source.

8. The device according to claim 7, wherein the light source comprises a laser diode.

9. A microscope, comprising:
the device for irradiating a sample according to claim 7.

10. A method for controlling a device for driving a light source for a microscope, the method comprising the steps of
generating a coarse driving current with a current source,
generating a fine driving current with a first signal generator,
driving the light source with a driving current resulting from the sum of the coarse driving current and of the fine driving current,
wherein the fine driving current has a magnitude smaller than the coarse driving current.

11. The method according to claim 10, further comprising the steps of:
receiving a feedback signal from a sensor for sensing light from a sample irradiated by the light source, the feedback signal being indicative of the amount of light measured by the sensor, and
adjusting the fine driving current based on the feedback signal.
